(19) United States
(12) Patent Application Publication
(10) Pub. No.: US 2011/0260175 A1
(43) Pub. Date: Oct. 27, 2011

(54) SEMICONDUCTOR DEVICE

(75) Inventors: Toru HIYOSHI, Osaka-shi (JP); Keiji WADA, Osaka-shi (JP); Takeyoshi MASUDA, Osaka-shi (JP)

(73) Assignee: SUMITOMO ELECTRIC INDUSTRIES, LTD., Osaka-shi (JP)

(21) Appl. No.: 13/092,683

(22) Filed: Apr. 22, 2011

(30) Foreign Application Priority Data
Apr. 27, 2010 (JP) 2010-101939

(51) Int. Cl. H01L 29/24

(52) U.S. Cl. 257/77; 257/E29.104

(57) ABSTRACT

A silicon carbide layer is provided on a substrate, has a hexagonal single-crystal structure, and has a surface at which a depletion layer is formed. A protective film is insulative and provided on the silicon carbide layer to directly cover the surface. The surface thus directly covered with the protective film includes a portion having an off angle of not more than 10° relative to the {0-33-8} plane of the silicon carbide layer. This results in reduced leakage current flowing in an interface between the protective film and the semiconductor layer.

### BACKGROUND OF THE INVENTION

1. Field of the Invention

The present invention relates to a semiconductor device having a silicon carbide layer.

2. Description of the Background Art

In recent years, substrates made of silicon carbide (SiC) having a hexagonal crystal structure have been adopted as semiconductor substrates for use in manufacturing semiconductor devices. Such a substrate is usually manufactured by slicing a SiC ingot obtained by growth in the {0001} plane, which is less likely to cause stacking fault. Hence, SiC substrates having plane orientations close to the {0001} plane are widely used.

For example, Japanese Patent Laying-Open No. 2009-088223 discloses a pn junction diode having a planar structure and utilizing a SiC substrate having a plane orientation inclined by eight degrees relative to the {0001} plane.

In a semiconductor device which utilizes a depletion layer formed in a silicon carbide layer to interrupt a current, one of methods for reducing leakage current is to reduce leakage current flowing on the surface of the depletion layer. If this method is employed, electric resistance in the surface of the silicon carbide layer has to be avoided from being decreased due to moisture from outside or ion attachment. Moreover, this surface needs to be protected from external physical interference. In view of these, a protective film is formed on the surface of the silicon carbide layer. However, even if such a protective film is formed, there are limitations in reducing the leakage current flowing on the surface using the conventional art.

### SUMMARY OF THE INVENTION

The present invention has been made in view of the foregoing problem, and its object is to provide a semiconductor device having reduced leakage current flowing in an interface between a protective film and a silicon carbide layer.

A semiconductor device of the present invention is a semiconductor device having a rectifying function provided by a depletion layer, and includes a substrate, a silicon carbide layer, and a protective film. The substrate is made of silicon carbide. The silicon carbide layer is provided on the substrate, has a hexagonal single-crystal structure, and has a surface at which the depletion layer is formed. The protective film is insulative and provided on the silicon carbide layer to directly cover the surface. The surface thus directly covered with the protective film includes a portion having an off angle of not more than 10° relative to a {0-33-8} plane of the silicon carbide layer.

According to the present invention, the surface at which the depletion layer faces the protective film includes the portion having an off angle of 10° relative to the {0-33-8} plane, i.e., portion with a particularly small interface state density. This restrains generation of leakage current resulting from the interface state, thereby obtaining a semiconductor device with a small leakage current.

Preferably, the silicon carbide layer has a pn junction for forming the depletion layer. Accordingly, the depletion layer can be formed by means of the pn junction.

Preferably, an interface between the portion of the surface of the silicon carbide layer and the protective film has an interface state density of not more than 5×10¹² cm² eV⁻¹. Accordingly, the surface at which the depletion layer faces the protective film includes a portion with a particularly small interface state density. This restrains generation of leakage current resulting from the interface state, thereby obtaining a semiconductor device with a small leakage current.

Preferably, the interface between the portion of the surface of the silicon carbide layer and the protective film contains nitrogen atoms. Accordingly, the interface state density is further reduced. This restrains generation of the leakage current resulting from the interface state, thereby obtaining a semiconductor device with a small leakage current.

Preferably, the silicon carbide layer has a planar structure. Accordingly, there can be obtained a semiconductor device with a small leakage current and a planar structure.

Preferably, the substrate includes a first layer facing the silicon carbide layer and a second layer supporting the first layer, and the second layer has an impurity concentration larger than that of the first layer. Accordingly, the conductivity of the second layer becomes large, thereby reducing on-resistance of the semiconductor device.

Preferably, the first layer has a threading dislocation density smaller than that of the second layer. This can reduce the threading dislocation density of the surface on which the silicon carbide layer is formed, thereby forming a silicon carbide layer with higher quality.

Preferably, the silicon carbide layer has a mesa structure. Accordingly, there can be obtained a semiconductor device with a small leakage current and a mesa structure.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view schematically showing a configuration of a diode serving as a semiconductor device in a first embodiment of the present invention.

FIG. 2 is a plan view schematically showing a configuration of a silicon carbide layer provided in the diode of FIG. 1.

FIG. 3 is a perspective view illustrating a hexagonal single-crystal structure of silicon carbide.

FIG. 4 is a plan view schematically showing a configuration of a silicon carbide substrate used in manufacturing the diode of FIG. 1.

FIG. 5 is a schematic cross sectional view taken along a line V-V in FIG. 4.

FIG. 6 is a cross sectional view schematically showing one step of a method for manufacturing the silicon carbide substrate of FIG. 4.

FIG. 7 is a graph showing a correlation between an interface state density and energy in band gap, in each of the present invention's example and comparative examples.

FIG. 8 is a cross sectional view schematically showing a configuration of a diode serving as a semiconductor device in a second embodiment of the present invention.

FIG. 9 is a cross sectional view schematically showing a configuration of a diode serving as a semiconductor device in a third embodiment of the present invention and taken along a line IX-IX of each of FIG. 10 and FIG. 11.

FIG. 10 and FIG. 11 are plan views schematically showing configurations of a silicon carbide layer and a protective layer provided in the diode of FIG. 9.

FIG. 12-FIG. 14 are cross sectional views schematically showing first to third steps of a method for manufacturing a diode of FIG. 9.

FIG. 15 is a plan view schematically showing a configuration of a silicon carbide layer of a variation of the diode of FIG. 9.

FIG. 16 is a cross sectional view schematically showing a configuration of a diode serving as a semiconductor device in a fourth embodiment of the present invention.

### DESCRIPTION OF THE PREFERRED EMBODIMENTS

The following describes embodiments of the present invention with reference to figures. It should be noted that crystallographically, a bar is supposed to be put above an index, but instead it is indicated by putting a negative sign before the index in the present specification.

### First Embodiment

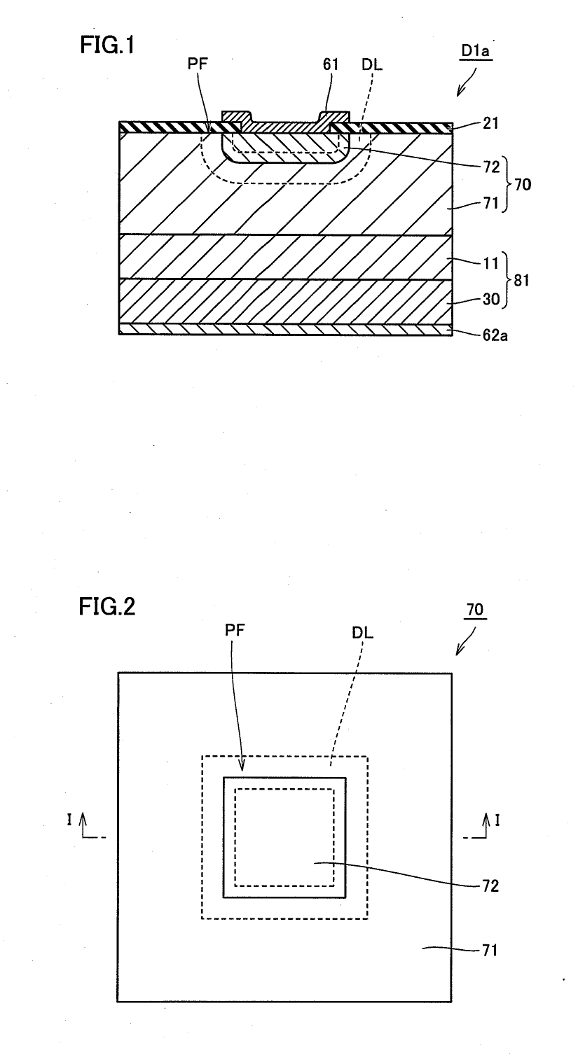

Referring to FIG. 1 and FIG. 2, a diode D1a (semiconductor device) of the present embodiment is a diode having a rectifying function provided by a depletion layer DL and having a planar structure. Diode D1a has a cathode electrode 62a, a substrate 81, a silicon carbide layer 70, a protective film 21, and an anode electrode 61.

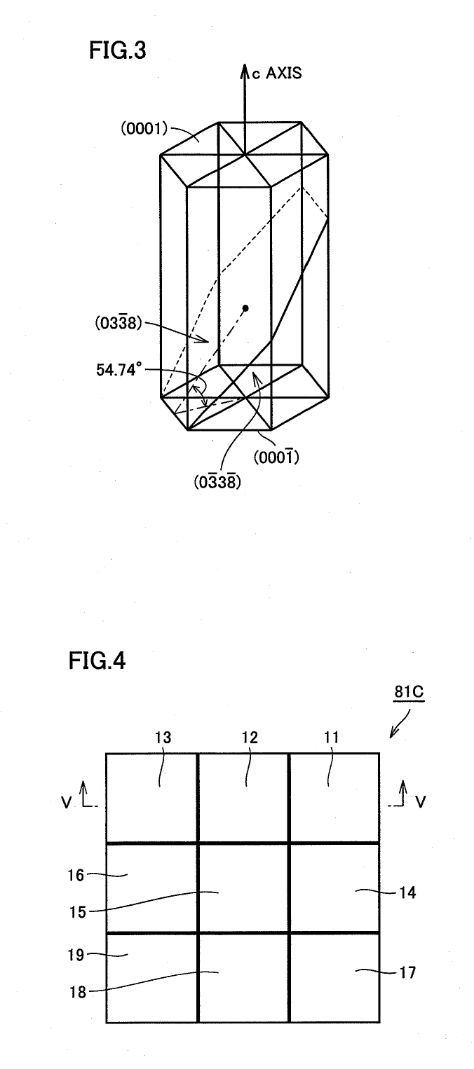

Substrate 81 is made of silicon carbide. Substrate 81 has a high-quality layer (first layer) 11 and a base layer (second layer) 30. High-quality layer 11 faces silicon carbide layer 70. Further, high-quality layer 11 has a hexagonal single-crystal structure (FIG. 3), and has a plane orientation of {0-33-8}. This single-crystal structure has a polytype of, for example, 4H. Base layer 30 supports high-quality layer 11. High-quality layer 11 has a threading dislocation density smaller than that of base layer 30. An Impurity is added to base layer 30 and high-quality layer 11 to provide them with the same conductive type. Base layer 30 has an impurity concentration larger than that of high-quality layer 11. This allows base layer 30 to have a conductivity larger than that of high-quality layer 11.

Silicon carbide layer 70 is epitaxially grown on high-quality layer 11, and is accordingly formed on substrate 81. Further, silicon carbide layer 70 has a hexagonal single-crystal structure (FIG. 3), and has a plane orientation of {0-33-8}. Furthermore, silicon carbide layer 70 has an n⁻ layer 71 and p layer 72. N⁻ layer 71 faces substrate 81 and has the same conductive type as that of substrate 81. P layer 72 is separated from substrate 81 by n⁻ layer 71. Further, n⁻ layer 71 and p layer 72, which have conductive types different from each other, are in contact with each other to constitute a pn junction for forming depletion layer DL. This pn junction has an end that reaches one surface of silicon carbide layer 70 (upper surface in FIG. 1 and surface shown in FIG. 2). Therefore, in this one surface, silicon carbide layer 70 has a surface PF at which depletion layer DL is formed. Because silicon carbide layer 70 has a plane orientation of {0-33-8}, surface PF also has a plane orientation of {0-33-8}.

Protective film 21 is provided on the above-described one surface of silicon carbide layer 70 (the upper surface in FIG. 1 and the surface shown in FIG. 2). Further, protective film 21, which has an opening from which a portion of p layer 72 is exposed, directly covers surface PF. Further, protective film 21 is an insulative film made of an oxide including silicon atoms and nitrogen atoms, and has a function of preventing contamination and physical interference onto surface PF.

It should be noted that in the present embodiment, surface PF has a plane orientation of {0-33-8}, but the plane orientation of surface PF is not limited to this. When the plane orientation of surface PF is {0-33-8} or is sufficiently close thereto, the above-described interface state density can be small. Specifically, surface PF has a plane orientation having an off angle of not more than 10° relative to the {0-33-8} plane of silicon carbide layer 70, more preferably, has an off angle of not more than 5°, and further preferably, has an off angle of 3°.

Further, in the upper surface of silicon carbide layer 70 (the upper surface in FIG. 1 and the surface shown in FIG. 2), a junction termination structure may be provided to surround the structure of the present embodiment shown in FIG. 2. An exemplary junction termination structure usable is a guard ring or a JTE (Junction Termination Extension). The junction termination structure can be formed by adding an impurity by means of ion implantation and activating this impurity by means of a heat treatment. Further, depletion layer DL is generated when a reverse bias is applied to the pn junction. Further, in the above-described configuration, the p type and the n type may be replaced with each other. Further, a film (not shown) may be provided on protective film 21 to protect protective film 21.

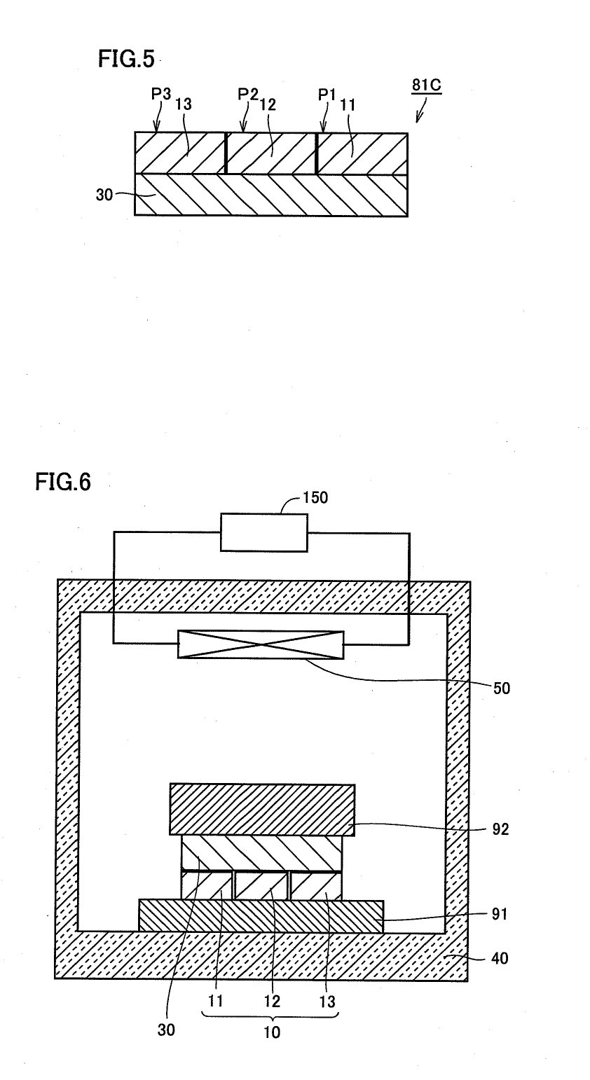

The following describes a method for manufacturing diode D1a. Referring to FIG. 4 and FIG. 5 mainly, a silicon carbide substrate 81C is prepared. Silicon carbide substrate 81C includes a portion that will be cut in dicing and accordingly formed into substrate 81 (FIG. 1). Silicon carbide substrate 81C has base layer 30, and high-quality layers 11-19 provided on base layer 30. Each of high-quality layers 12-19 is the same as high-quality layer 11 described above. It should be noted that a method for manufacturing silicon carbide substrate 81C will be described later.

Next, n⁻ layer 71 is formed on each of high-quality layers 11-19 by epitaxial growth. Next, p layer 72 is formed by means of ion implantation and activation. The ion implantation can be performed to correspond to the planar shape of p layer 72 (FIG. 2), using a mask pattern formed by means of a photolithography technique. In this way, silicon carbide layer 70 including n⁻ layer 71 and p layer 72 is formed.

Then, the surface of silicon carbide layer 70 is cleaned, and is thermally oxided. This thermal oxidation treatment is performed under a temperature of 1200° C. and an atmosphere of oxygen of 100% for 60 minutes, for example. The cleaning before the thermal oxidation is, specifically, organic cleaning, acid cleaning, or so-called RCA cleaning.

Then, heat treatment is performed under an atmosphere containing nitrogen atoms. This atmosphere is formed, for example, using a nitrogen oxide, specifically, using NO (nitrogen monoxide) gas or N₂O (dinitrogen monoxide). Further, for example, the temperature of the heat treatment is not less than 1100° C. and not more than 1300° C., and the heating time is not less than 30 minutes and not more than 120 minutes. By this heat treatment, protective film 21, which is an insulative silicon oxide film, is formed.

After the heat treatment, additional heat treatment may be performed in an inert gas. For example, under an Ar atmosphere, heat treatment may be performed at a temperature of 1100° C. for 60 minutes. Further, a film (not shown) for protecting protective film 21 may be further provided.

Next, a portion of protective film 21 is selectively removed by means of the photolithography technique, thereby forming an opening in protective film 21 to partially expose p layer 72 therefrom. Then, anode electrode 61 is formed on and in ohmic contact with p layer 72 thus exposed. Meanwhile, cathode electrode 62a is formed on and in ohmic contact with base layer 30. Accordingly, diode D1a is obtained.

The following describes a method for manufacturing silicon carbide substrate 81C described above.

Referring to FIG. 6, base layer 30 and high-quality layers 11-19 (also collectively referred to as “layer group 10”) are prepared. Each one in layer group 10 thus prepared is a single-crystal silicon carbide substrate. Base layer 30 thus prepared is not limited to one with single-crystal and may be of polycrystal. In the case where base layer 30 is of single-crystal, base layer 30 may have a threading dislocation density higher than that of layer group 10. Thus, a high-quality single-crystal such as layer group 10 does not need to be used for base layer 30 and may be a sintered compact, for example. Hence, a base layer larger in size than each one in layer group 10 can be readily prepared.

Further, a heating device is prepared which has first and second heating members 91, 92, a heat insulation container 40, a heater 50, and a heater power source 150. Heat insulation container 40 is formed of a highly thermally insulating material. Heater 50 is, for example, an electric resistance heater. First and second heating members 91, 92 have a function of absorbing heat emitted from heater 50 and emitting the absorbed heat so as to heat base layer 30 and layer group 10. Each of first and second heating members 91, 92 is formed of, for example, graphite with a small porosity.

Next, first heating member 91, layer group 10, base layer 30, and second heating member 92 are arranged to be stacked on one another in this order. Specifically, first, high-quality layers 11-19 are arranged on first heating member 91 in the form of a matrix. Next, base layer 30 is placed on layer group 10. Then, second heating member 92 is placed on base layer 30. Then, first heating member 91, layer group 10, base layer 30, and second heating member 92 thus stacked on one another are accommodated in heat insulation container 40 having heater 50 provided therein.

Then, the atmosphere of heat insulation container 40 is adapted to be an inert gas. An exemplary inert gas usable is a noble gas such as He or Ar; a nitrogen gas; or a mixed gas of the noble gas and nitrogen gas. Further, the pressure in heat insulation container 40 is preferably 50 kPa or smaller, and is more preferably 10 kPa or smaller.

Next, heater 50 heats layer group 10 and base layer 30 by means of first and second heating members 91, 92 to a temperature at which sublimation/recrystallization reaction takes place. This heating is performed to cause a temperature difference such that the temperature of base layer 30 becomes higher than the temperature of layer group 10. This temperature difference can be formed by, for example, disposing heater 50 closer to second heating member 92 relative to first heating member 91 as shown in FIG. 6.

When the temperature of base layer 30 becomes higher than the temperature of each one in layer group 10 as described above, mass transfer takes place due to sublimation and recrystallization in a minute gap between each one in layer group 10 and base layer 30 in a direction from base layer 30 toward layer group 10. This brings each one in layer group 10 and base layer 30 into connection with each other. Further, as a result of the sublimation from base layer 30 and the recrystallization onto layer group 10, the crystal structure of base layer 30 is changed into a crystal structure corresponding to that of layer group 10. For example, even if base layer 30 initially prepared has a polycrystal structure, the crystal structure of base layer 30 connected to layer group 10 can be a single-crystal structure. It should be noted that the quality of the single-crystal of this base layer 30 is inferior to that of layer group 10 and the single-crystal of base layer 30 has a threading dislocation density higher than that of each one in high-quality layers 11-19.

In this way, silicon carbide substrate 81C is obtained.

Preferably, as the inert gas introduced into heat insulation container 40, a gas containing nitrogen is used. The nitrogen atoms are included in base layer 30 in course of the above-described sublimation and recrystallization. This results in a high n type impurity concentration in base layer 30 of silicon carbide substrate 81C, which leads to a high threading dislocation density in base layer 30.

According to the present embodiment, the surface at which depletion layer DL (FIG. 1) faces protective film 21, i.e., surface PF has a plane orientation of {0-33-8}. Accordingly, leakage current flowing in surface PF having depletion layer DL formed thereat is reduced while diode D1a is in the off state. This effect is considered to be provided by a small interface state density in surface PF of diode D1a. This is because such a small interface state density restrains current, generated due to an interface state, in the leakage current flowing via surface PF of diode D1a that is in the off state. The following describes a result of inspection with regard to this interface state density.

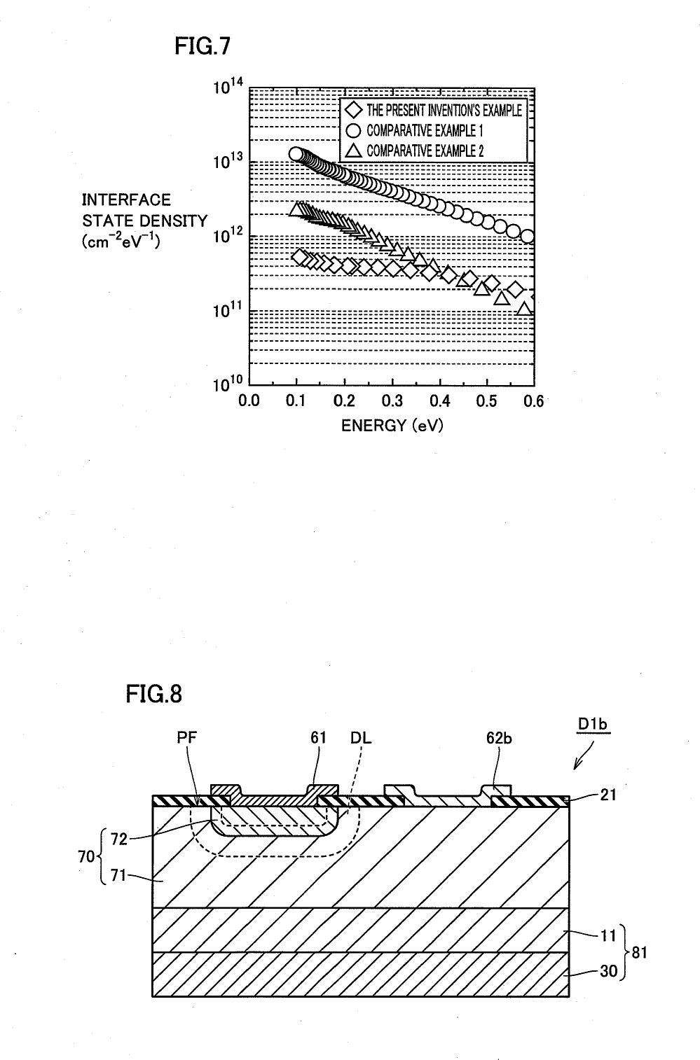

Referring to FIG. 7, in the case where surface PF had a plane orientation of {0-33-8} and heat treatment was performed under atmosphere using NO as described above in the present embodiment, an interface state density in an interface between protective film 21 and silicon carbide layer 70 was, for example, as indicated by each of diamond-shaped markers as “the present invention's example” in the graph. On the other hand, in the case where the heat treatment was not performed, the interface state density was, for example, as indicated by each of circular markers as “comparative example 1” in the graph. Meanwhile, in the case where the heat treatment was performed but surface PF had a plane orientation of {0001} rather than {0-33-8}, the interface state density was, for example, as indicated by each of triangular markers as “comparative example 2” in the graph. From the comparison among these three examples, it was found that the interface state density in the present invention's example is low in most of an energy region, and is particularly low in a low energy region. Specifically, it was found that by performing the heat treatment under the atmosphere containing nitrogen atoms, nitrogen atoms are introduced into the interface between protective film 21 and silicon carbide layer 70, thereby obtaining an interface state density of not more than 5×10¹² cm⁻² eV⁻¹. In addition, it was found that in the case where such heat treatment is performed and surface PF has a plane orientation of {0-33-8}, the interface state density is significantly decreased.

### Second Embodiment

Referring to FIG. 8, a diode D1b (semiconductor device) of the present embodiment is a lateral type diode unlike diode D1a (FIG. 1), and has a cathode electrode 62b instead of cathode electrode 62a. Cathode electrode 62b is provided on n⁻ layer 71. According to the present embodiment, an effect similar to that in the first embodiment can be obtained in diode D1b of lateral type.

In order to reduce contact resistance of cathode electrode 62b, a contact portion of n⁻ layer 71 with cathode electrode 62b may be provided with a region having a high impurity concentration (not shown). Such a region can be formed by, for example, ion implantation.

### Third Embodiment

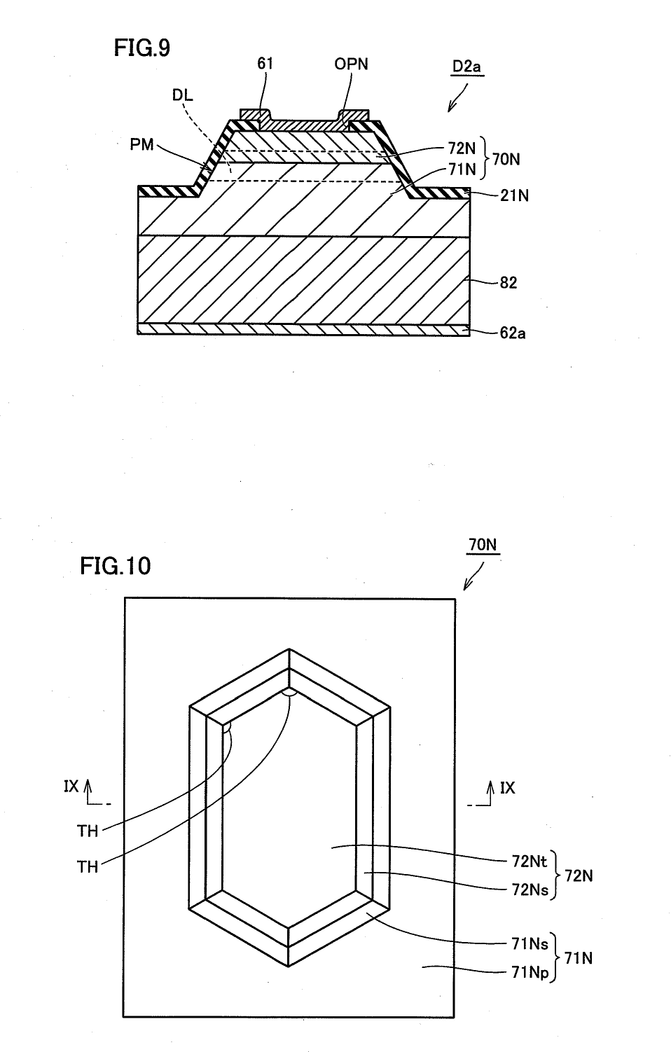

Referring to FIG. 9-FIG. 11, a diode D2a (semiconductor device) of the present embodiment is a diode having a rectifying function provided by depletion layer DL, and having a mesa structure. Diode D2a has a cathode electrode 62a, a substrate 82, a silicon carbide layer 70N, a protective film 21N, and an anode electrode 61.

Substrate 82 is made of silicon carbide having a hexagonal single-crystal structure (FIG. 3). This single-crystal structure has a polytype of, for example, 4H. Further, substrate 82 has one surface facing silicon carbide layer 70N and having a plane orientation of {0001}. The other surface of substrate 82 faces cathode electrode 62a.

Silicon carbide layer 70N is epitaxially grown on substrate 82 and is accordingly formed thereon, and has a hexagonal single-crystal structure (FIG. 3). Further, silicon carbide layer 70N has an if layer 71N and a p layer 72N. N⁻ layer 71N faces substrate 82, and has the same conductive type as that of substrate 82. P layer 72N is separated from substrate 82 by if layer 71N. Further, if layer 71N and p layer 72N, which have conductive types different from each other, are in contact with each other to constitute a pn junction for forming depletion layer DL. Further, silicon carbide layer 70N has a mesa structure. Specifically, as the mesa structure, silicon carbide layer 70N has a mesa portion 72Nt, side portions 72Ns, 71Ns, and an outer peripheral portion 71Np. Mesa portion 72Nt and side portion 72Ns constitute a surface of p layer 72, whereas side portion 71Ns and outer peripheral portion 71Np constitute a surface of n⁻ layer 71N. Mesa portion 72Nt of the mesa structure has a plane orientation of {0001}, and has a hexagon planar shape. Each angle TH in this hexagon is 120°. Each of side portions 72Ns, 71Ns of the mesa structure has a plane orientation of {0-33-8}. The above-described pn junction has an end that reaches side portions 72Ns, 71Ns of the mesa structure. Therefore, in side portions 72Ns, 71Ns, silicon carbide layer 70N has a surface PM at which depletion layer DL is formed. Because side portions 72Ns, 71Ns have a plane orientation of {0-33-8}, surface PM also has a plane orientation of {0-33-8}.

Protective film 21N directly covers side portions 72Ns, 71Ns of the mesa structure. Hence, protective film 21N directly covers surface PM. Further, protective film 21N has an opening OPN at mesa portion 72Nt of the mesa structure. Via opening OPN, anode electrode 61 and p layer 72N are in contact with each other. Opening OPN preferably has a planar shape of hexagon, which more preferably has each angle of 120°. Protective film 21N is an insulative film made of an oxide including silicon atoms and nitrogen atoms, and has a function of preventing contamination and physical interference onto surface PM.

It should be noted that in the present embodiment, surface PM has a plane orientation of {0-33-8}, but the plane orientation of surface PM is not limited to this. An interface state density in an interface between protective film 21N and silicon carbide layer 70N can be reduced as long as the plane orientation of this interface is {0-33-8} or close thereto as described in the first embodiment. Hence, surface PM has a plane orientation having an off angle of not more than 10° relative to the {0-33-8} plane of silicon carbide layer 70N, more preferably, has an off angle of not more than 5°, and further preferably, has an off angle of 3°.

Further, a junction termination structure may be provided on outer peripheral portion 71Np (FIG. 10) to surround the mesa structure. As the junction termination structure, for example, a guard ring or a JTE can be used. The junction termination structure can be formed by adding an impurity by means of ion implantation and activating this impurity by means of heat treatment. Further, in the above-described configuration, the p type and the n type may be replaced with each other. Further, a film (not shown) may be provided on protective film 21N to protect protective film 21N.

The following describes a method for manufacturing diode D2a.

Referring to FIG. 12, n⁻ layer 71L and p layer 72L are formed on substrate 82 in this order by means of epitaxial growth. P layer 72L may be formed by means of ion implantation. Next, a mask layer 61L is formed on p layer 72L. Mask layer 61L is a silicon oxide layer, for example. Next, a photoresist layer 62L is formed on mask layer 61L. Next, in order to provide photoresist layer 62L with a shape corresponding to the mesa structure of diode D2a, photoresist layer 62L is exposed to light and is developed.

Referring to FIG. 13, by the exposure and development, a mask 62 is formed. Mask 62 has a structure corresponding to the mesa structure of diode D2a. Next, using mask 62, mask layer 61L is etched to pattern mask layer 61L.

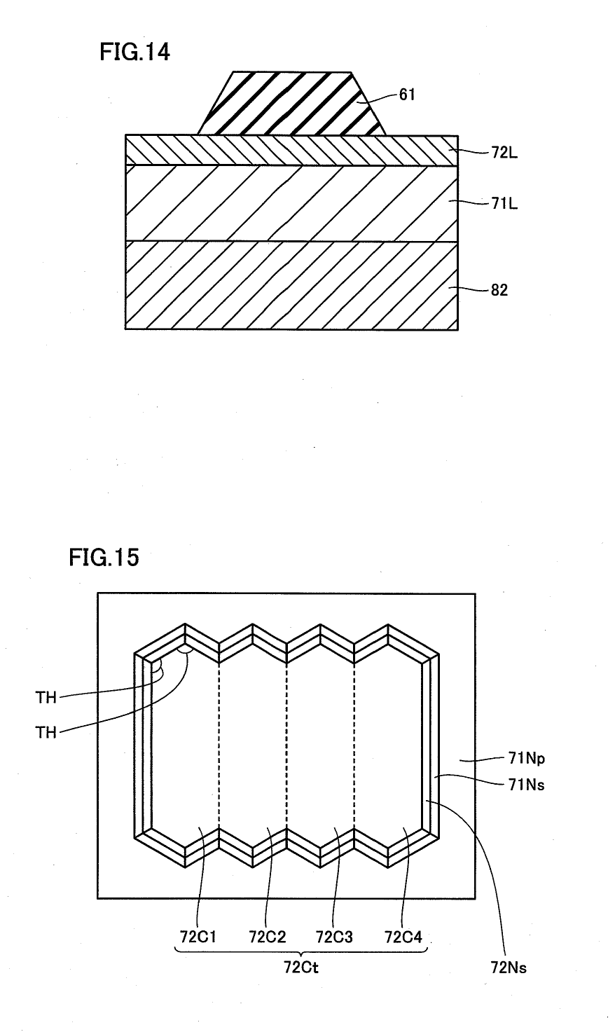

Referring to FIG. 14 mainly, a mask 61 is formed by the patterning. Using mask 61, p layer 72L is etched, and n⁻ layer 71L is etched partially in the direction of thickness, thereby forming the mesa structure of silicon carbide layer 70N (FIG. 9).

Then, the surface of silicon carbide layer 70N is cleaned, and is thermally oxided. This thermal oxidation treatment is performed under a temperature of 1200° C. and an atmosphere of oxygen of 100% for 60 minutes, for example. The cleaning before the thermal oxidation is, specifically, organic cleaning, acid cleaning, or so-called RCA cleaning.

Then, heat treatment is performed under an atmosphere containing nitrogen atoms. This atmosphere is formed, for example, using a nitrogen oxide, specifically, using NO gas or N₂O. Further, for example, the temperature of the heat treatment is not less than 1100° C. and not more than 1300° C., and the heating time is not less than 30 minutes and not more than 120 minutes. By this heat treatment, protective film 21N, which is an insulative silicon oxide film, is formed.

After the heat treatment, additional heat treatment may be performed in an inert gas. For example, under an Ar atmosphere, heat treatment may be performed at a temperature of 1100° C. for 60 minutes. Further, a film (not shown) for protecting protective film 21N may be further provided.

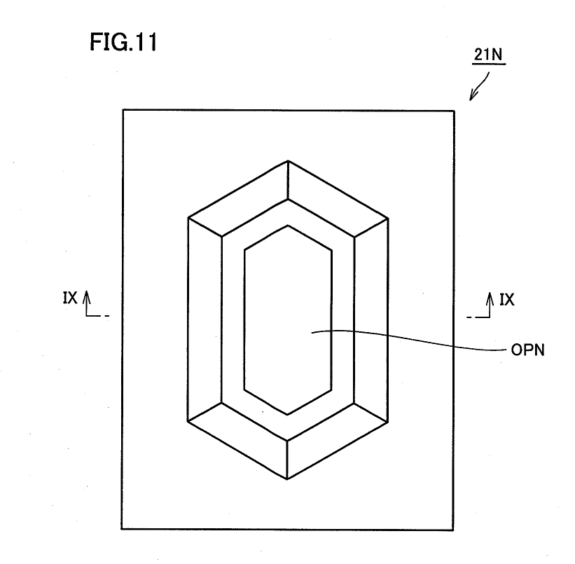

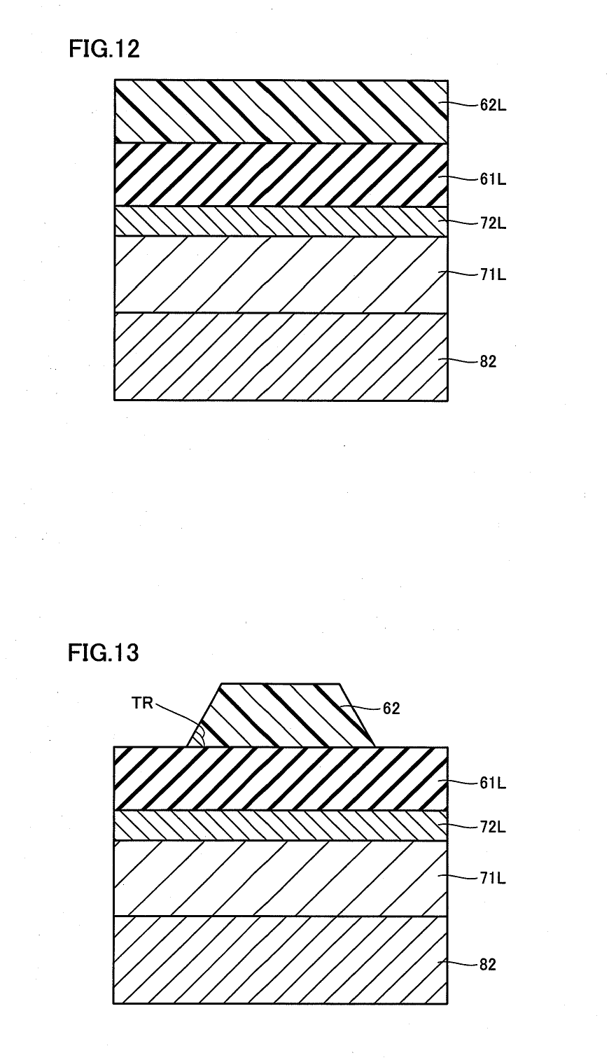

Next, a portion of protective film 21N is selectively removed by means of the photolithography technique, thereby forming opening OPN (FIG. 11) on protective film 21N. Then, anode electrode 61 is formed on and in ohmic contact with p layer 72N (FIG. 9) exposed in opening OPN. Meanwhile, cathode electrode 62a is formed on and in ohmic contact with substrate 82. Accordingly, diode D2a is obtained.

According to the present embodiment, the surface at which depletion layer DL (FIG. 9) faces protective film 21N, i.e., surface PM has a plane orientation of {0-33-8}. Accordingly, leakage current flowing in surface PM having depletion layer DL formed thereat is reduced while diode D2a is in the off state. This effect is considered to be provided by a small interface state density in surface PM of diode D2a. This is because such a small interface state density restrains current, generated due to an interface state, in the leakage current flowing via surface PM of diode D2a that is in the off state, as described in the first embodiment.

Although FIG. 10 shows that mesa portion 72Nt of the mesa structure has the shape of hexagon elongated in one direction (vertical direction in the figure), the shape of the mesa portion of the mesa structure is not limited to this. The shape of the mesa portion may be a right hexagon, for example. In this case, there is obtained a diode having a more symmetrical shape. Alternatively, the mesa portion may be formed by combining a plurality of mesa portions 72C1-72C4 each having a shape of hexagon, as indicated by a mesa portion 72Ct (FIG. 15). Because the shape constituted by one hexagon or a plurality of hexagons is utilized, the entire side portions 71Ns, 72Ns of the mesa structure can have a plane orientation of {0-33-8} or a plane orientation close thereto in the hexagonal system.

### Fourth Embodiment

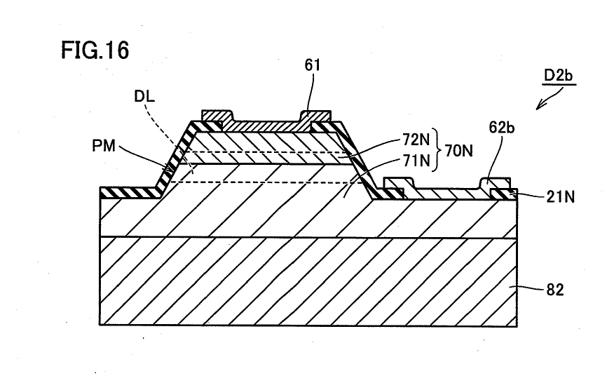

Referring to FIG. 16, a diode D2b (semiconductor device) of the present embodiment is a lateral type diode unlike diode D2a (FIG. 9), and has a cathode electrode 62b instead of cathode electrode 62a. Cathode electrode 62b is provided on n⁻ layer 71N. According to the present embodiment, an effect similar to that of the third embodiment can be obtained in diode D2b of lateral type.

In order to reduce contact resistance of cathode electrode 62b, a contact portion of n⁻ layer 71N with cathode electrode 62b may be provided with a region having a high impurity concentration (not shown). Such a region can be formed by, for example, ion implantation.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device having a rectifying function provided by a depletion layer, the semiconductor device comprising:
a substrate made of silicon carbide;
a silicon carbide layer provided on said substrate, having a hexagonal single-crystal structure, and having a surface at which said depletion layer is formed; and
a protective film, which is insulative and provided on said silicon carbide layer to directly cover said surface, said surface thus directly covered with said protective film including a portion having an off angle of not more than 10° relative to a {0-33-8} plane of said silicon carbide layer.

2. The semiconductor device according to claim 1, wherein said silicon carbide layer has a pn junction for forming said depletion layer.

3. The semiconductor device according to claim 1, wherein an interface between said portion of said silicon carbide layer and said protective film has an interface state density of not more than 5×10¹² cm⁻² eV⁻¹.

4. The semiconductor device according to claim 3, wherein said interface contains nitrogen atoms.

5. The semiconductor device according to claim 1, wherein said silicon carbide layer has a planar structure.

6. The semiconductor device according to claim 5, wherein said substrate includes a first layer facing said silicon carbide layer and a second layer supporting said first layer, and said second layer has an impurity concentration larger than that of said first layer.

7. The semiconductor device according to claim 6, wherein said first layer has a threading dislocation density smaller than that of said second layer.

8. The semiconductor device according to claim 1, wherein said silicon carbide layer has a mesa structure.
